(19) United States
(12) Patent Application Publication
(10) Pub. No.: US 2016/0323998 A1
(43) Pub. Date: Nov. 3, 2016

(54) Substrate Material Favoring Via Hole Electroplating

(71) Applicant: Fameson Technology Co., Ltd., Taipei City (TW)

(72) Inventor: Rong-Seng CHANG, Taipei City (TW)

(21) Appl. No.: 14/698,635

(22) Filed: Apr. 28, 2015

(51) Int. Cl. H05K 1/03

(52) U.S. Cl. CPC H05K 1/0373

(57) ABSTRACT

The present invention proposes substrate material favoring via hole electroplating to overcome the conventional problem that the polymer-based printed circuit board is hard to conduct electricity and likely to have poor electroplating quality. The present invention adds a conductive material to a polymeric material and controls the proportions and structure thereof to form a substrate material so as to improve the affinity of the substrate material to the metal electroplated inside the via hole with the resistance of the substrate material remaining in an allowable range. Thereby is increased yield and efficiency and saved time and cost in fabricating printed circuit boards. Further, the present invention reduces the proportion of the polymeric material with the mechanical strength remaining in an allowable range so as to decrease the overall expansion rate and obtain a fire-proof effect. Therefore, the substrate material can be used to fabricate precision products.

### BACKGROUND OF THE INVENTION

1. Field of the Invention

The present invention relates to a substrate material, particularly to a substrate material favoring via hole electroplating, wherein a conductive material is added to the substrate material to improve the quality of the circuits inside the via holes.

2. Description of the Related Art

At present, manufacturers normally adopt polymeric materials, especially epoxy resins, as the substrate materials for printed circuit boards. A multilayer printed circuit board needs via holes to interconnect the circuits on different layers. The wall of a via-hole is metalized for electric conduction by electroplating. However, polymeric materials have high insulativity, which impairs electroplating in via holes. Thus, the conductive substance electroplated on the walls of the via holes is hard to adhere to the substrate firmly but likely to peel off from the substrate, which degrades the electric conductivity of via holes. Then, the reliability of printed circuit boards is decreased, and the fabrication cost of printed circuit boards is increased.

Hence, the Inventor develops a substrate material favoring via hole electroplating, which can improve the affinity of the substrate material to the conductive substance electroplated inside via holes and prevent the conductive substance from peeling off from the via holes, whereby to upgrade the quality of the circuits inside via holes and overcome the abovementioned problems.

### SUMMARY OF THE INVENTION

The primary objective of the present invention is to provide a substrate material favoring via hole electroplating, wherein a conductive material is added to a substrate material with the ratio and structure thereof controlled to make the resistance of the substrate material within an allowable range, whereby the affinity of the polymer-based substrate material to metal is improved in electroplating, wherefore the yield is increased and the time and cost of fabrication is saved.

Another objective of the present invention is to provide a substrate material favoring via hole electroplating, wherein the proportion of the polymeric material is reduced with the mechanical strength thereof remaining within an allowable range, whereby the overall expansion rate is decreased and the fire-resistance is increased, wherefore the substrate material can be used to fabricate precision products.

To achieve the abovementioned objectives, the present invention proposes a substrate material favoring via hole electroplating, which comprises a polymeric material be used in an amount of 20-50 parts by weight; a filling material be used in an amount of 20-50 parts by weight; and a conductive material be used in an amount of 2-20 parts by weight and having a particle size of 0.1-10 μm.

In the present invention, the polymeric material is selected from a group consisting of rubbers, silicone rubbers, fluorine rubbers, epoxy resins, polyimide (PI) resins, polyurethane (PU) resins, acrylonitrile butadiene styrene (ABS) resins, and acrylic resins. The filling material is selected from a group consisting of aluminum hydroxide (Al(OH)₃), calcium carbonate, talcum powder, phosphate esters, and melamine-cyanuric acid (MCA) complexes. The conductive material is selected from a group consisting of silicon compounds, graphite, silver, copper, and aluminum.

In one embodiment, the substrate material favoring via hole electroplating of the present invention further comprises a non-metallic compound be used in an amount of 22 parts by weight at most and having at least two particle sizes. In one embodiment, the non-metallic compound is a mixture of two groups of particles respectively having particle sizes of less than 0.5 μm and greater than 30 μm. The non-metallic compound is selected from a group consisting of boron nitride (BN), silicon dioxide (SiO₂), titanium dioxide (TiO₂), zinc oxide (ZnO), aluminum oxide (Al₂O₃) and aluminum nitride (AlN).

Through adding a conductive material to the substrate material, the present invention can increase the adhesion of the electroplated material to the via hole and improve the quality of the circuit inside the via hole. Further, the present invention decreases the proportion of the polymeric material to decrease the overall expansion rate and enhance the fire resistance. The substrate material favoring via hole electroplating of the present invention is applicable to fabricate various types of printed circuit boards, particularly high-precision products.

Below, embodiments are described in detail to make easily understood the objectives, technical contents, characteristics and accomplishments of the present invention.

### BRIEF DESCRIPTION OF THE DRAWINGS

FIG. 1 is a sectional view schematically showing a printed circuit board using the substrate material favoring via hole electroplating according to one embodiment of the present invention;

FIG. 2 shows the relationship between the proportion of the conductive material added to a polymeric material and the specific resistance of the polymeric material according to the present invention, wherein the curves respectively represent the relationships of the conductive materials: silver, copper, aluminum, graphite, and a silicon compound from left to right;

FIG. 3 shows the relationship between the proportion of the polymeric material and the mechanical strength of the polymeric material according to the present invention; and

FIG. 4 shows the relationship between the proportion of the polymeric material and the expansion rate of the polymeric material according to the present invention.

### DETAILED DESCRIPTION OF THE INVENTION

The present invention provides a substrate material favoring via hole electroplating, which comprises a polymeric material be used in an amount of 20-50 parts by weight; a filling material be used in an amount of 20-50 parts by weight; a conductive material be used in an amount of 2-20 parts by weight; and a non-metallic compound be used in an amount of 0-22 parts by weight.

In the present invention, the polymeric material is selected from a group consisting of rubbers, silicone rubbers, fluorine rubbers, epoxy resins, polyimide (PI) resins, polyurethane (PU) resins, acrylonitrile butadiene styrene (ABS) resins, and acrylic resins. The filling material is selected from a group consisting of aluminum hydroxide (Al(OH)₃), calcium carbonate, talcum powder, phosphate esters, and melamine-cyanuric acid (MCA) complexes. The conductive material is selected from a group consisting of silicon compounds, graphite, silver, copper, and aluminum. The conductive material has a particle size of 0.1-10 μm, preferably 3 μm. The non-metallic compound is selected from a group consisting of boron nitride (BN), silicon dioxide (SiO₂), titanium dioxide (TiO₂), zinc oxide (ZnO), aluminum oxide (Al₂O₃) and aluminum nitride (AlN). The non-metallic compound has at least two particle sizes. In other words, at least two sizes of particles exist in the non-metallic compound simultaneously. In one embodiment, the non-metallic compound is a mixture of two groups of particles respectively having particle sizes of less than 0.5 μm and greater than 30 μm.

It should be noted: the amounts mentioned in the specification are based on number of parts by weight. In the present invention, the amounts for the components of the substrate material is polymeric material: filling material: conductive material: non-metallic material=20-50(parts by weight): 20-50(parts by weight): 2-20(parts by weight): 0-22(parts by weight). In other words, 20-50 parts by weight of the filling material, 2-20 parts by weight of the conductive material, and 0-22 parts by weight of the non-metallic material is used for 20-50 parts by weight of the polymeric material. The weights of the components can be directly derived from the parts by weight easily. For example, 20-50 g of the filling material, 2-20 g of the conductive material, 0-22 g of the non-metallic material is used for 20-50 g of the polymeric material.

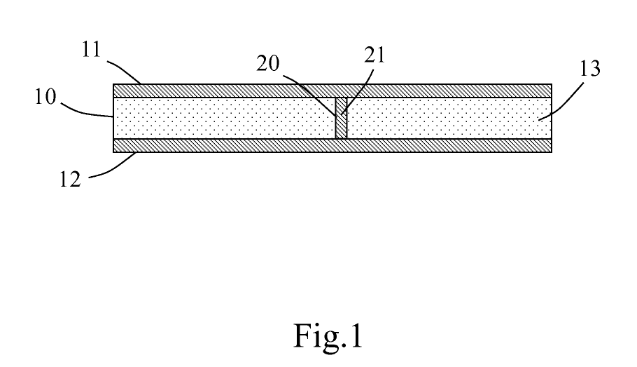

The substrate material favoring via hole electroplating of the present invention can be used to fabricate a substrate of a printed circuit board whose via holes are demanded to have electric conductivity. Refer to FIG. 1 a sectional view schematically showing a printed circuit board using the substrate material favoring via hole electroplating according to one embodiment of the present invention.

In this embodiment, the substrate 10 of a printed circuit board is fabricated with the substrate material favoring via hole electroplating of the present invention. A via hole 20 penetrates the substrate 10 and has a conductive substance 21 on the wall thereof One end of the conductive material 21 is electrically connected with a first circuit surface 11, and the other end of the conductive substance 21 is electrically connected with a second circuit surface 12. Thereby, the conductive substance 21 electrically interconnects the first circuit surface 11 and the second circuit surface 12. The substrate material favoring via hole electroplating of the present invention is characterized in having a conductive material 13, which can increase the adhesion of the conductive substance 21 to the via hole 20 and make the conductive substance 21 less likely to peel off from the substrate 10. Therefore, the present invention can enhance the quality of the circuit inside the via hole 20. Besides, the present invention further adds a non-metallic compound to the substrate material to improve fire resistance and upgrade the performance of the products.

Below are introduced the experiments of the resistance and physical properties of different substrate materials to demonstrate the design principle and efficacies of the substrate material favoring via hole electroplating of the present invention.

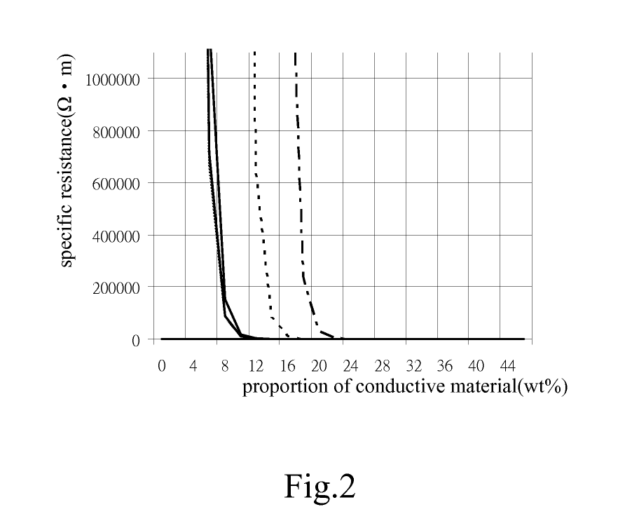

Refer to FIG. 2 showing the relationship between the proportion of the conductive material added to a polymeric material and the specific resistance of the polymeric material. The data of the proportions of the conductive material and the specific resistances of the polymeric material are also shown in Table.1.

TABLE 1

| Proportion of | | | | | | Proportion of |
|---|---|---|---|---|---|---|
| Conductive | | | | | Silicon | Polymeric |
| Material (wt %) | Silver | Copper | Aluminum | Graphite | Compound | Material (wt %) |
| 0 | 3.44E+08 | 365072220 | 6.23E+08 | 1E+11 | 1E+11 | 100 |
| 2 | 42949673 | 45634027.5 | 77846282 | 2E+10 | 1E+11 | 98 |
| 4 | 5368709 | 5704253.44 | 9730785 | 3E+09 | 1E+11 | 96 |
| 6 | 671088.6 | 713031.68 | 1216348 | 3E+08 | 1E+11 | 94 |
| 8 | 83886.08 | 89128.96 | 152043.5 | 4E+07 | 8E+09 | 92 |
| 10 | 10485.76 | 11141.12 | 19005.44 | 5E+06 | 1E+09 | 90 |
| 12 | 1310.72 | 1392.64 | 2375.68 | 655360 | 1E+08 | 85 |
| 14 | 163.84 | 174.08 | 296.96 | 81920 | 2E+07 | 80 |
| 16 | 20.48 | 21.76 | 37.12 | 10240 | 2E+06 | 75 |
| 18 | 2.56 | 2.72 | 4.64 | 1280 | 240000 | 70 |
| 20 | 0.32 | 0.34 | 0.58 | 160 | 30000 | 65 |
| 22 | 0.04 | 0.0425 | 0.0725 | 20 | 3750 | 60 |
| 24 | 0.008 | 0.0085 | 0.0145 | 4 | 750 | 55 |
| 26 | 0.0016 | 0.0017 | 0.0029 | 0.8 | 150 | 50 |
| 28 | 0.00032 | 0.00034 | 0.00058 | 0.16 | 30 | 45 |
| 30 | 0.000064 | 0.000068 | 0.000116 | 0.032 | 6 | 40 |
| 32 | 1.28E−05 | 0.0000136 | 2.32E−05 | 0.0064 | 1.2 | 35 |
| 34 | 2.56E−06 | 0.00000272 | 4.64E−06 | 0.0013 | 0.24 | 30 |
| 36 | 5.12E−07 | 5.44E−07 | 9.28E−07 | 0.0003 | 0.048 | 25 |
| 38 | 2.56E−07 | 2.72E−07 | 4.64E−07 | 0.0001 | 0.024 | 20 |
| 40 | 1.28E−07 | 1.36E−07 | 2.32E−07 | 6E−05 | 0.012 | 15 |
| 42 | 6.4E−08 | 6.8E−08 | 1.16E−07 | 3E−05 | 0.006 | 10 |
| 44 | 3.2E−08 | 3.4E−08 | 5.8E−08 | 2E−05 | 0.003 | 5 |
| 46 | 1.6E−08 | 1.7E−08 | 2.9E−08 | 8E−06 | 0.0015 | 0 |

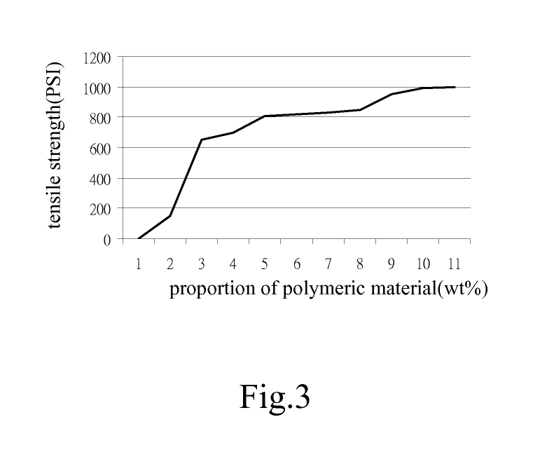

Refer to FIG. 3 showing the relationship between the proportion of the polymeric material and the mechanical strength of the polymeric material. The data of the proportions of the polymeric material and the mechanical strengths of the polymeric material are also shown in Table.2.

TABLE 2

| Proportion of | Mechanical |
|---|---|
| Polymeric Material | Strength |
| (wt %) | (PSI) |
| 0 | 0 |
| 10 | 150 |
| 20 | 650 |
| 30 | 700 |
| 40 | 810 |
| 50 | 820 |
| 60 | 830 |
| 70 | 850 |
| 80 | 950 |
| 90 | 990 |
| 100 | 1000 |

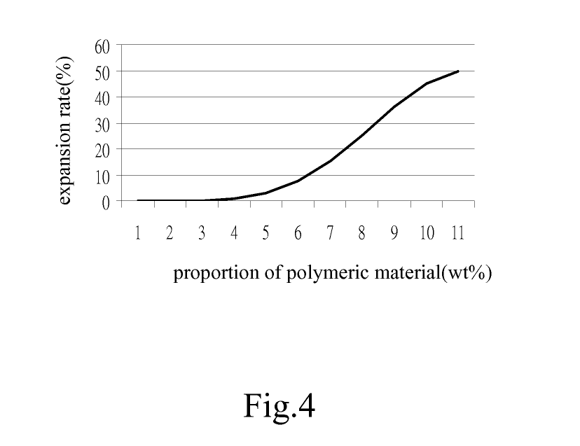

Refer to FIG. 4 showing the relationship between the proportion of the polymeric material and the expansion rate of the polymeric material. The data of the proportions of the polymeric material and the expansion rates of the polymeric material are also shown in Table.3.

TABLE 3

| Proportion of | Expansion |
|---|---|
| Polymeric Material | Rate |
| (wt %) | (%) |
| 0 | 0 |
| 10 | 0.018144 |
| 20 | 0.18144 |
| 30 | 0.9072 |
| 40 | 3.024 |
| 50 | 7.56 |
| 60 | 15.12 |
| 70 | 25.2 |
| 80 | 36 |
| 90 | 45 |
| 100 | 50 |

In conclusion, the present invention proposes a substrate material favoring via hole electroplating, which is characterized in adding a conductive material to a polymeric material to improve the electric conductivity of the polymeric material. The present invention controls the proportions of the components and the structure of the substrate material so that the affinity of the via hole to the electroplated metal can be effectively improved with the resistance of the substrate material remaining in an allowable range. Thereby, the present invention can increase the yield and efficiency of fabrication and save the time and cost of fabrication. Further, the present invention reduces the proportion of the polymeric material with the mechanical strength of the substrate material remaining in an allowable range so as to decrease the overall expansion rate and obtain a fire-proof effect. Therefore, the substrate material of the present invention can be used to fabricate precision products.

The embodiments described above are only to exemplify the present invention but not to limit the scope of the present invention. Any equivalent modification or variation according to the characteristic or spirit of the present invention is to be also included within the scope of the present invention.

What is claimed is:

1. A substrate material favoring via hole electroplating, comprising a polymeric material be used in an amount of 20-50 parts by weight parts by weight;
a filling material be used in an amount of 20-50 parts by weight; and
a conductive material be used in an amount of 2-20 parts by weight and having a particle size of 0.1-10 μm.

2. The substrate material favoring via hole electroplating according to claim 1, wherein said polymeric material is selected from a group consisting of rubbers, silicone rubbers, fluorine rubbers, epoxy resins, polyimide (PI) resins, polyurethane (PU) resins, acrylonitrile butadiene styrene (ABS) resins, and acrylic resins.

3. The substrate material favoring via hole electroplating according to claim 1, wherein said filling material is selected from a group consisting of aluminum hydroxide (Al(OH)₃), calcium carbonate, talcum powder, phosphate esters, and melamine-cyanuric acid (MCA) complexes.

4. The substrate material favoring via hole electroplating according to claim 1, wherein said conductive material is selected from a group consisting of silicon compounds, graphite, silver, copper, and aluminum.

5. The substrate material favoring via hole electroplating according to claim 1, wherein said conductive material has a particle size of less than 3 μm.

6. The substrate material favoring via hole electroplating according to claim 1 further comprising a non-metallic compound that be used in an amount of at most 22 parts by weight and having at least two particle sizes.

7. The substrate material favoring via hole electroplating according to claim 6, wherein said non-metallic compound is a mixture of two groups of particles respectively having particle sizes of less than 0.5 μm and greater than 30 μm.

8. The substrate material favoring via hole electroplating according to claim 6, wherein said non-metallic compound is selected from a group consisting of boron nitride (BN), silicon dioxide (SiO₂), titanium dioxide (TiO₂), zinc oxide (ZnO), aluminum oxide (Al₂O₃) and aluminum nitride (AlN).

9. The substrate material favoring via hole electroplating according to claim 1, which is used to fabricate printed circuit boards.
